(19) United States
(12) Patent Application Publication
(10) Pub. No.: US 2017/0372578 A1
(43) Pub. Date: Dec. 28, 2017

(54) Apparatus for Power Distribution, Environment Monitoring and Fire Protection for Rack-Mounted Equipment

(71) Applicant: AKCess Pro Limited, Bangkok (TH)

(72) Inventors: Bradley Klein, Bangkok (TH); Charles Meyer, Bangkok (TH); Scott Farnum, Bangkok (TH); Nicholas Barrowclough, Clark (PH)

(21) Appl. No.: 15/195,241

(22) Filed: Jun. 28, 2016

(51) Int. Cl. G08B 17/10; H02H 5/00; A62C 35/13; H05K 7/14; A62C 3/16

(52) U.S. Cl. CPC G08B 17/10; H05K 7/1495; H05K 7/1492; A62C 3/16; A62C 35/13; H02H 5/00

(57) ABSTRACT

A 0U, rack-mounted, power distribution, environment monitoring, and fire-protection apparatus including an environmental monitoring sensor system, including a fire detection and protection system located in a computer rack. The invention includes a system to localize damage to equipment, business interruption, and hazardous conditions to a computer rack.

### BACKGROUND OF THE INVENTION

### Field of the Invention

The invention pertains to the field of power distribution equipment in racks. More particularly, the invention pertains to using power distribution equipment to protect rack-mounted electronic equipment from fire damage.

### Description of Related Art

The spread of fires within the data center has long been a concern to data center managers. The need to monitor conditions that affect the safety of the computer equipment and the people within the data center has resulted in the use of specially designed fire protection systems. Existing fire protection solutions, while effective in ensuring the safety of the data center equipment can be ineffective in terms of business expense and hazardous to the health of the data center workers.

Large scale data center fire protection systems protect computer equipment within the data center as a whole rather than within the computer rack. These systems can result in the shutdown of the entire data center because of a localized fire. The data center fire protection systems are deployed on a large scale rather than a compartmentalized, computer rack level. Once triggered, these large scale safety systems cause disruptions to the data center affecting many computer racks. Often these systems release a fire extinguishant that is dangerous to the personnel working in the data center. The extinguishant can result in the death of people working in the data center at the time of the release.

There are existing fire protection systems located within the computer racks. However these systems take up much of the limited and valuable space available within the rack. These rack oriented fire protection systems usually take space in the computer rack that could otherwise hold as many as two servers, and do not have integrated power shutdown facilities.

The rack oriented fire protection systems of the prior art requires the data center administrator to deal with a separate vendor from the equipment already in his rack such as the power distribution unit (PDU). The rack oriented fire protection systems of the prior art also need to be separately managed and controlled from other equipment already in the rack such as the PDU. This causes an unnecessary burden to the data center administrator to learn, maintain, and manage. The separate rack oriented fire protection systems are often not centrally controlled, configured or monitored.

Power distribution units or PDUs within a data center may be mounted in unused space within the rack, in a configuration referred to by the industry as “0U”. The 0U space is usually located at the rear of the rack (although mounting in unused space at the front of the rack is also possible), and therefore does not take space used by rack mounted computer equipment. PDUs in 0U space are usually mounted vertically.

U.S. Pat. No. 4,447,846, for a “Computer environment protector” shows a protective apparatus that monitors temperature, smoke detection and current consumption and that shuts down electrical equipment. The apparatus lacks a fire extinguisher, is not rack-mounted, lacks network connectivity and has no 0U configuration.

U.S. Pat. No. 5,365,568 for a “Smoke detector with automatic dialing”, shows a system that monitors several alarm inputs and that shuts down power and reports via a modem upon alarm condition signals state. The system lacks a fire extinguisher, is not rack-mounted, and has no 0U configuration.

U.S. Pat. No. 7,423,543, for a “Multifunctional relay module for use with CO and smoke alarms” shows a system with multiple detectors that turns ON or OFF a relay upon the sensed detector conditions. The system lacks a fire extinguisher, is not rack-mounted, lacks network connectivity and has no 0U configuration.

U.S. Pat. No. 7,471,195, for an “Emergency power shutdown management system” shows a management system that controls power shutdown of electrical equipment and activates alarm upon received alarm signals such as fire suppression discharge. The system requires a fire control panel, lacks network connectivity and lacks a 0U configuration.

U.S. Pat. No. 7,796,047, for an “Apparatus for fire detection in an electrical equipment rack” shows a rack mounted apparatus to detect fire or smoke and that issues alarm signals upon fire detection. The system lacks a 0U configuration and has no integrated power distribution and power control to shut down equipment.

U.S. Pat. No. 7,099,934, for a “Network-connecting power manager for remote appliances” shows a PDU with controlled outlets, environmental sensor power shut-down equipment upon receipt of remote signals. It lacks a local sensor controlled power shut-down system, a fire extinguisher and smoke detector.

### SUMMARY OF THE INVENTION

The invention describes an apparatus that uses a power distribution unit combined with an environment monitoring sensor system combined with a fire alarm and protection system. This invention is located in an enclosure mounted in otherwise unused “0U” space within a computer rack. This invention is used to protect the equipment located within the computer rack. Sensors, particularly smoke detectors, associated with this invention safely and securely detect conditions that could cause a disruption in service. The invention may then isolate and protect the rack thereby limiting the service interruption to the equipment located within the computer rack and limiting the exposure of personnel to hazardous conditions. Network connectivity is provided through a communications interface in the control module.

The invention integrates the PDU with environmental monitoring sensors, smoke detectors and fire protection system while adding novel features. This invention locally manges manage safety conditions within the computer rack, thereby preventing the unsafe conditions to affect large areas of the data center. The invention is used to rapidly shut down the equipment contained within the rack before the problem is detected by the safety systems that protect the entire data center. Therefore business outages may be limited to a specific rack or to a subset of equipment located with the rack and the personnel within the data center are protected from life threatening fire extinguishant.

By shutting off the flow of air into and out of the rack, the extent of the smoke entering the computer data center is thereby limited. By controlling the shutdown of computer equipment within the rack, the data within the computer is maintained, thereby shortening the time by which the data center is placed back in operation after a fire event. By controlling the power to fans and associated air conditioning units, the flow of air to the rack is diminished. By integrating the PDU into a central management system the data center administrator is able to control and manage a large number of racks.

One embodiment of this invention has the ability to shut down individual computer systems on a selective basis, treating each computer with its own special requirements. These special requirements may include shutdown commands issued from the invention to selected computers, commands issued may transfer data or workload from an affected computer, or delay the removal of power from affected computers.

By combining the features of the traditional PDU, environment monitoring sensor system and fire protection equipment, the amount of space taken in the rack is greatly reduced. By combining the management of the PDU, environment monitoring sensor system and the fire protection equipment into a single command module the learning time and overall management overhead is reduced. By dealing with a single vendor for three important functions within the rack, the data center manager is less burdened. By combining the PDU, environment monitoring sensor system and the fire protection equipment into a single unit, the cost to manufacture is greatly reduced through the elimination of duplicate material.

The unique insight of this invention combines the power distribution unit with an environmental monitoring sensor system combined with a fire alarming and suppression system in a computer rack in a way that has been undiscovered. The new invention is ideally suited to sensing and preventing safety issues within the computer rack.

Unlike prior art rack oriented fire protection equipment, the PDU of the invention has the ability to shut down individual computer equipment since it controls the power to the equipment within the rack. The shutdown sequence can be altered by the PDU so that computer equipment that requires a controlled shutdown can be given the time and proper commands from the PDU. The PDU further may have the ability to separately shut down fans and air conditioning units and to individually close air handling systems preventing air from entering or leaving the rack.

One embodiment of the invention can monitor the status of two or more smoke detectors in order to prevent shutting down the equipment contained within the rack due to a false alarm from one of the smoke detectors. By having an alarm status formed as a logical combination of more than one smoke detectors, the triggering mechanism is more reliable, reducing the likelihood of a false alarm. Therefore unintended business outages may be avoided saving unnecessary downtime costs due to false alarms.

### BRIEF DESCRIPTION OF THE DRAWING

FIG. 1 shows a typical computer rack which includes several server computers powered by a monitored Power Distribution Unit.

FIG. 2 shows a computer rack which includes several server computers powered by a monitored Power Distribution Unit.

FIG. 3 shows a computer rack which includes several server computers powered by a monitored Power Distribution Unit.

FIG. 4 illustrates an example of Web Interface of an embodiment to configure the shutdown of a computer upon detection of smoke.

FIG. 5 illustrates an example of Web Interface of an embodiment to configure the release of fire extinguishing agent upon detection of smoke.

FIG. 6 illustrates an example of Web Interface of an embodiment to configure the shutdown of a computer upon detection of smoke.

FIG. 7 illustrates an example of Web Interface of an embodiment to configure the shutdown of a computer and the release of fire extinguishing agent upon detection of smoke.

FIG. 8 illustrates an example of Web Interface of an embodiment to configure the shutdown of a computer and the release of fire extinguishing agent upon delayed detection of smoke.

FIG. 9 illustrates an example of Web Interface of an embodiment to configure the shutdown of a computer and the release of fire extinguishing agent upon detection of smoke.

FIG. 10 shows a block diagram of the invention.

### DETAILED DESCRIPTION OF THE INVENTION

The illustrative embodiments provide mechanisms for a power distribution and environment monitoring and fire suppression device located in a computer rack to power down server computers and other electrical appliances located in and related to the computer rack and to release fire extinguishing agent within the computer rack, upon the detection of smoke and, optionally, high temperatures. The power down execution and the release of fire extinguishing agent can be delayed according to predetermined policies and characteristics. For example, the predetermined policies that may request a power down upon smoke detection. The policy could also include a temperature sensor measurement exceeding a critical threshold, a dry contact alarm from an external Fire Management System in critical state, detection of the presence of water or other harmful environmental conditions. In such cases, the device would trigger a power down of the electrical appliances located in the computer rack and optionally the release of fire extinguishing agent in order to suppress a fire inside the computer rack. The invention could also close louvers, turn off fans or stop air conditioner to prevent air to feed and increase a fire or to prevent smoke from exiting the cabinet. In addition a separate smoke evacuation pathway may be opened.

Embodiments generally relate to the device triggering commands to power down electrical equipment in a computer rack and, optionally, to release fire extinguishing agent in order to limit damages, along with additional commands to prevent fire propagation.

In embodiments described below, the device triggers different action policies that powers down electrical equipment in a computer rack and releases fire extinguishing agent upon the detection of smoke.

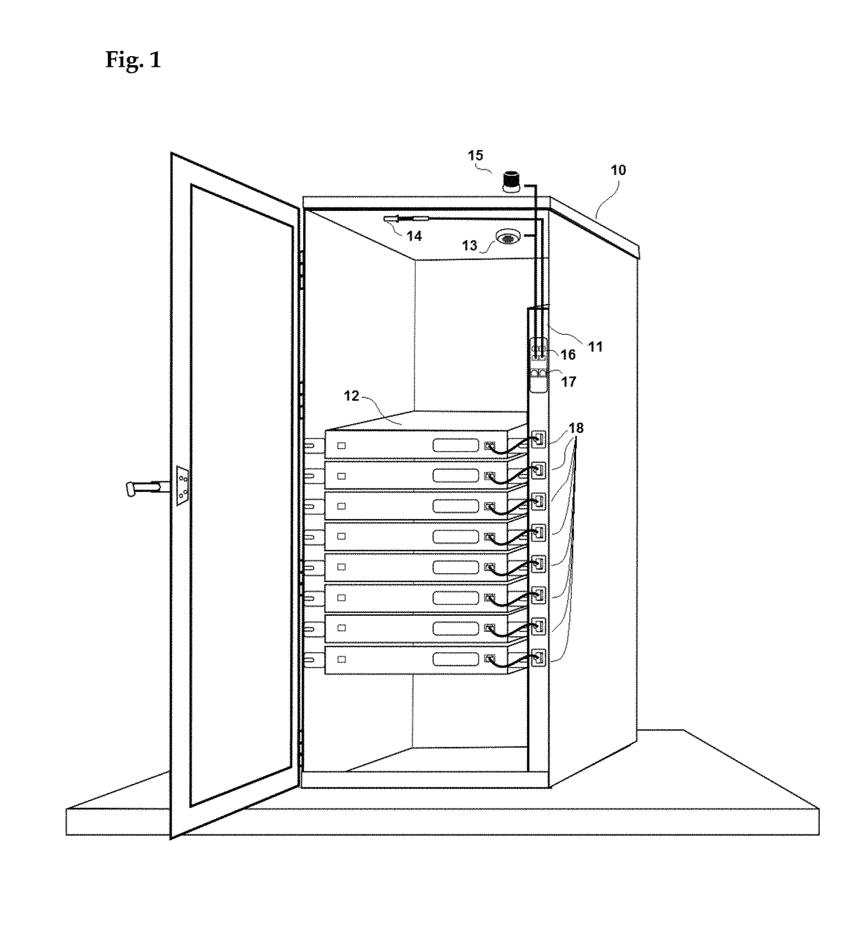

With reference to FIG. 1, in the depicted example is a typical computer rack 10 environment that includes computer servers 12 connected to power-controlled outlets 18 of a 0U, rack-mounted, power distribution, environment monitoring, and fire-protection unit 11, the PDU comprises sensor interfaces 16 and communication interfaces 17. The PDU monitors different sensors such as smoke detector 13, temperature 14, and a siren and/or strobe 15 that is turned on when an alarm is triggered.

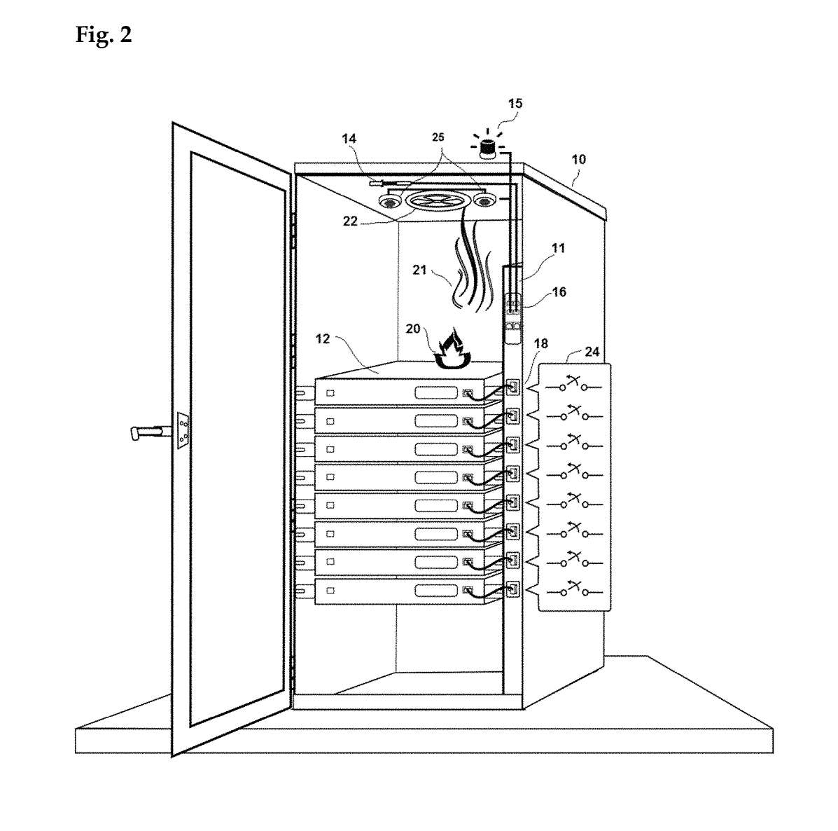

With reference to FIG. 2, in the depicted example is a computer rack 10 environment that includes computer servers 12 connected to power-controlled outlets 18 of a 0U, rack-mounted, power distribution, environment monitoring, and fire-protection unit 11, illustrating an embodiment of the invention. The 0U, rack-mounted, power distribution, environment monitoring, and fire-protection 11 comprises sensor interfaces 16 which are used for monitoring different sensors such as two smoke detectors 25, a temperature sensor 14, and controlling an annunciator for providing an audible or visible alarm, such as a siren or strobe 15, and a cooling fan 22. When smoke 21, due to a fire 20 is detected by both of the two smoke detectors 25 and, optionally, the internal rack temperature 14 is at a critical level due to the heat of the fire 20, the 0U, rack-mounted, power distribution, environment monitoring, and fire-protection 11 triggers commands to open all its internal power-control relays 24, cutting the electrical power supply at the power-controlled outlets 18. The 0U, rack-mounted, power distribution, environment monitoring, and fire-protection 11 will also turn on the siren and/or strobe 15 in order to signal a critical event in the rack and turn off the air cooling fan 22, preventing fire to expand.

It should be noted that there may be many sensors monitored by the system, including at least one smoke detector. The additional sensors could include additional smoke detectors at different locations in the rack, as well as different types of sensors such as one or more hydrogen sensors, water detectors, dry contact input sensors, voltage measurement sensors, current measurement sensors, voltage presence sensors, motion detectors, humidity sensors, pressure sensors, airflow sensors, dust detection sensors, and light sensors. Where a system uses multiple sensors, false alarms can be reduced if the system is programmed such that when a smoke detector sends a signal to the controller, the controller waits for a confirmatory signal from at least one other sensor before raising an alarm.

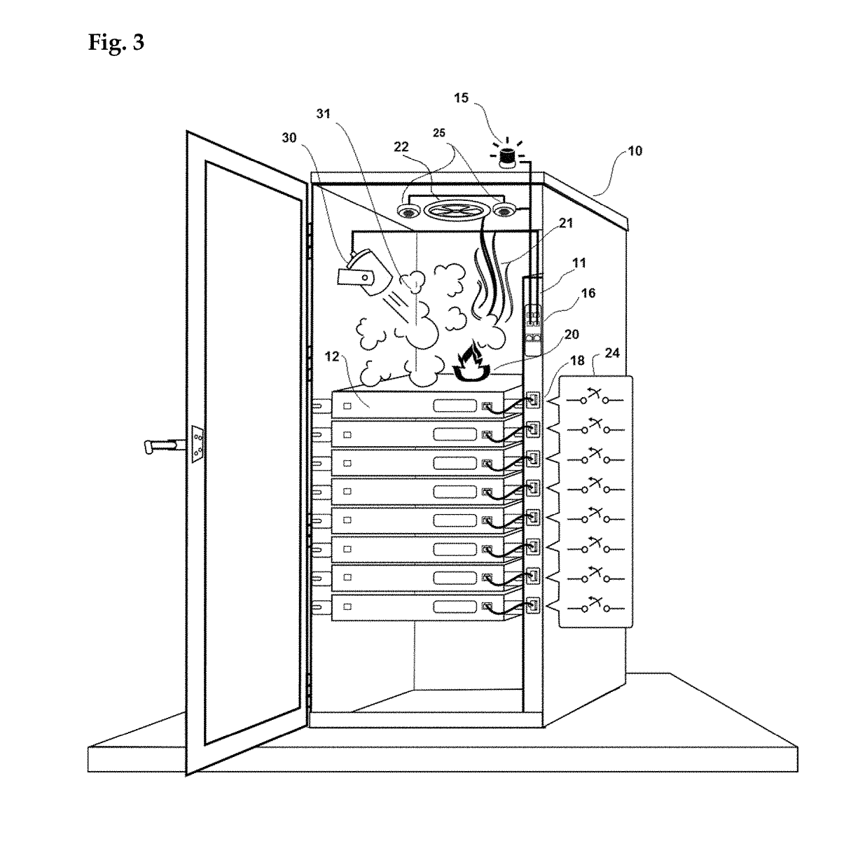

With reference to FIG. 3, in the depicted example is a computer rack 10 environment that includes computer servers 12 connected to power-controlled outlets 18 of a 0U, rack-mounted, power distribution, environment monitoring, and fire-protection unit 11, illustrating an embodiment of the invention. The 0U, rack-mounted, power distribution, environment monitoring, and fire-protection 11 comprises sensor interfaces 16 which are used for monitoring two smoke detectors 25, and for controlling a siren and/or strobe 15 and a cooling fan 22 and a fire extinguisher container 30. When smoke 21, due to a fire 20 is detected by one or, optionally, both of the smoke detectors 25, the 0U, rack-mounted, power distribution, environment monitoring, and fire-protection 11 triggers commands to open all its internal power-control relays 24, cutting the electrical power supply at the power-controlled outlets 18. The 0U, rack-mounted, power distribution, environment monitoring, and fire-protection 11 will also turn on the siren and/or strobe 15 in order to signal a critical event in the rack, turn off the air cooling fan 22, preventing fire to expand and releasing extinguishant 31 from the container 30 in order to suppress the fire 20.

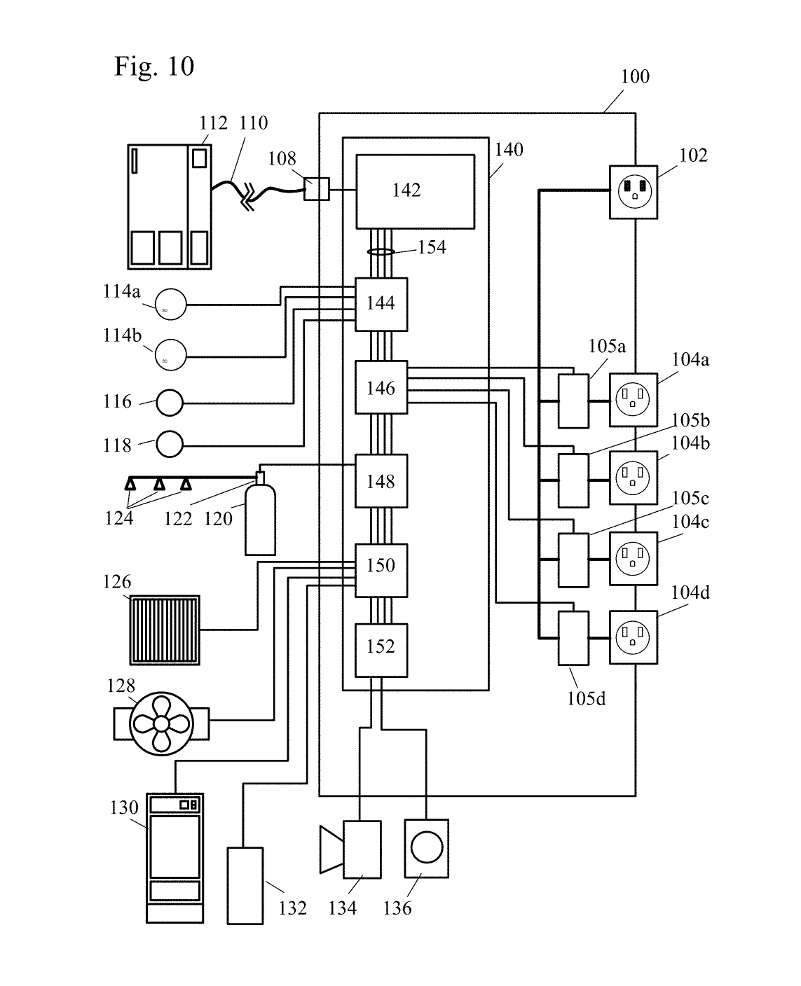

FIG. 10 shows a block diagram of the rack-mounted power distribution, environment monitoring, and fire-protection system for protecting equipment mounted in the rack, of the invention. As can be seen in FIG. 10, the control components of the system are mounted in an enclosure 100 mounted in a 0U configuration in unused space in the rack (10 in FIGS. 1-3, not shown in FIG. 10). A power input 102 in the enclosure 100 is connected to a number of control relays, here shown as four power-control relays 105a to 105d, although it will be understood that the specific number of relays and outlets is a matter of choice and does not form part of the invention. Each power-control relay 105a-105d can connect or disconnect power from the power input 102 to one or more outlets, shown in FIG. 10 as 104a-104d, under the control of signals on a control input. The outlets 104a-104d provide power for the various pieces of electronic equipment in the rack. Although the power input and the power outlets are shown in the figure as conventional three-prong AC connections, it will be understood that this is for example purposes, and any sort of power connection could be used as needed for a particular application, within the teachings of the invention.

A control module 140 in the enclosure 100 provides interfaces and control for the system. In the embodiment shown in the figure, the control module 140 comprises a main controller 142, which has a processor with memory and a communication interface with a communication port 108 for communicating with a remote user system 112 through a network 110, which may be a local area network (LAN), wide area network (WAN) or a global or regional network such as the Internet. The main controller 142 communicates with a number of separate controllers or interfaces—144, 146, 148, 150 and 152 in the embodiment shown in FIG. 10—which provide the inputs and outputs of the control module 140. In the embodiment shown in FIG. 10, this communication between the main controller 142 and the separate controllers or interfaces is done through a bus 154 into which the controllers or interfaces 144, 146, 148, 150 and 152 and the main controller 142 are plugged, although it will be understood that other means of communications are possible within the teachings of the art, for example by direct wiring or by wireless or optical links.

The interfaces and controllers in the embodiment of FIG. 10 will be described next, but it will be understood that the specific modules shown in the figure are for example purposes and a system could include more or fewer interfaces and controllers than those shown in the figures within the teachings of the invention. It should also be understood that while the block diagram of FIG. 10 shows separate boxes for the various logical components—controllers, interfaces, sensors, etc.—it is not intended by this block diagram to limit the invention to any particular arrangement of physical components.

Each component might be on a separate board, plugging into a rack with a bus interconnection, as is known to the art. Alternatively, some or all of the interfaces and controllers could also be combined with the processor and memory of the main controller onto a motherboard, with or without sockets connected to a bus on the board as is known to the computer art, within the teachings of the invention. Some or all of the interfaces and controllers could also be combined as parts of a single integrated component rather than as separate components within the teachings of the invention.

For example, an auxiliary equipment controller could be provided to combine the functions of some or all of controllers 148, 150, 152, or a controller could be combined with a sensor interface. For example, the fire extinguisher controller 148 and sensor interface 144 to which smoke detectors 114a and 114b are coupled could be combined in a single fire protection controller.

At least one sensor interface 144 will be coupled to the processor of the main controller 142. The sensor interface 144 will have at least one sensor input which is coupled to one or more external sensors including at least one smoke detector 114a located in the rack 10. In the example of FIG. 10, a second smoke detector 114b is shown, which permits the system to reduce false alarms by comparing readings from the two smoke detectors 114a and 114b, as described elsewhere herein.

Other sensors can be coupled to the sensor inputs of the sensor interface 144 or there may be more than one sensor interface 144, each coupled to a different sensor or group of sensors. These other sensors can include, for example, a heat detector 116, hydrogen sensor 118, water detector, dry contact input sensor, voltage measurement sensor, current measurement sensor, power measurement sensor, voltage presence sensor, motion detector, humidity sensor, pressure sensor, airflow sensor, dust detection sensor, or light sensor.

A power-control interface 146 will be coupled to the processor of the main controller 142. The power-control interface will have at least one power-control output coupled to the control input of at least one power-control relay. This can be implemented as shown in FIG. 10, where power-control interface 146 has separate power-control outputs, each output coupled to one of the power-control relays 105a-105d, which permits separate control of each relay 105a-105d. Thus, the relays can be controlled so that the power shutdown is done sequentially in a timed fashion. Alternatively, multiple power-control relays can be coupled to a single power-control output within the teachings of the invention. In the simplest embodiment, a single power-control output from the power-control interface 146 can be coupled to a single power-control relay (or to all of the relays in a single system), such that power to all of the outlets 104a-104d is disconnected simultaneously.

A fire extinguisher controller 148 can be provided, coupled to the processor of the main controller 142. The fire extinguisher controller has an output for triggering a fire extinguishing agent container 120, for example by opening a valve 122 and releasing fire extinguishing agent through heads 124 into the rack.

An annunciator controller 152 can optionally be coupled to the processor of the main controller 142. The annunciator controller 152 can have one or more outputs coupled to audible annunciators 134 such as horns, buzzers, loudspeakers or sirens or the like, and to visual annunciators 136 such as lights or strobes or displays. This permits the processor to cause an audible or visual alarm to be provided.

One or more auxiliary equipment controllers 150 can also be provided, coupled to the processor of the main controller 142. The auxiliary equipment controller 150 can be used to shut down other equipment, such as a fan 128 or air conditioner 130, or to close air louvers 126, as desired. Or, the auxiliary equipment controller 150 could be connected to a dry contact output, relay, or valve sensor, and other equipment controlled by those attachments.

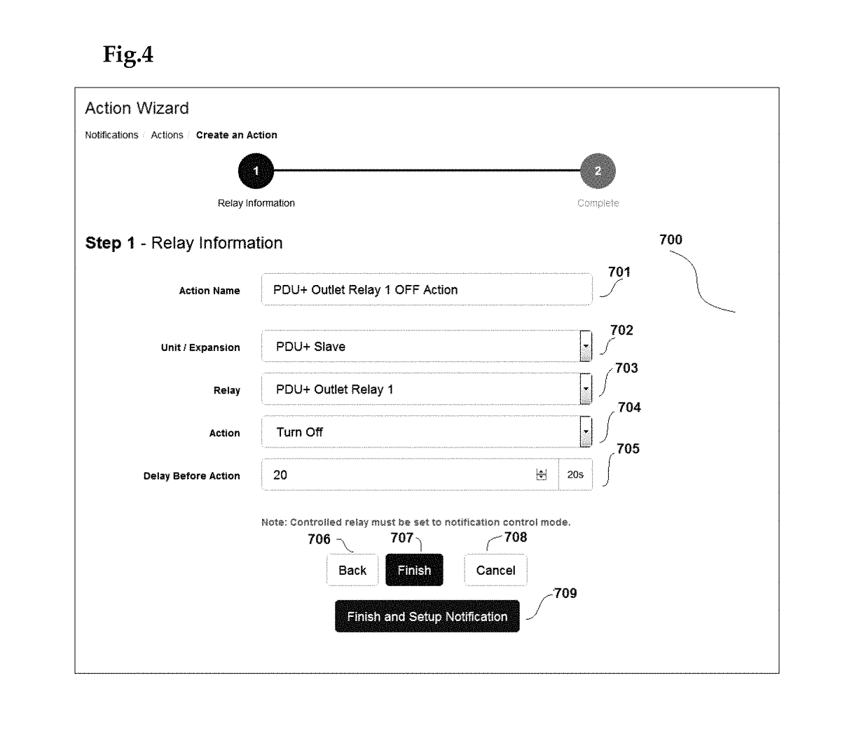

With reference to FIG. 4-9, the figures illustrate an embodiment of a Web interface of a PDU to configure in few steps an action policy and notification policy which purpose is to power down an electrical appliance connected to a switched outlet of the PDU when smoke is detected.

In FIG. 4, the figure depicts a relay action policy configuration web page 700, the user is able to define a name description 701 to the action policy, and select the unit 702 in case several slave units are connected to the same master unit and the relay 703 of that the user wants to control, then the user defines the type of command among a list of commands 704, here to turn off the corresponding outlet relay and finally the user is able to add a delay 705 in the execution of the command. When finished configuring the parameters of the action policy, the user is able either to go back to previous page 706, finish and store the action policy parameters 707, cancel the action policy configuration 708 or to start configuring a notification policy 709.

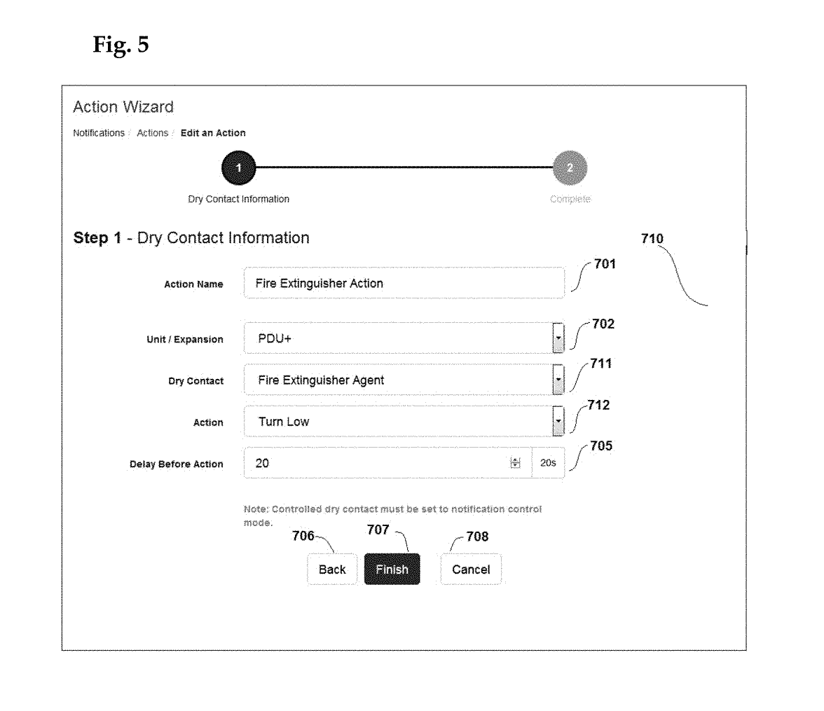

In FIG. 5, the figure depicts a Dry Contact action policy editing configuration web page 710, the user is able to edit a name description 701 to the action policy, and select the unit 702 in case several slave units are connected to the same master unit and the Fire Extinguisher Agent release output 711 that the user wants to control, then the user defines the type of command among a list of commands 712, here to turn Low the corresponding output to release the Fire Extinguisher Agent, and finally the user is able to add a delay 705 in the execution of the command. When finished configuring the parameters of the action policy, the user is able either to go back to previous page 706, finish and store the action policy parameters 707, cancel the action policy configuration 708.

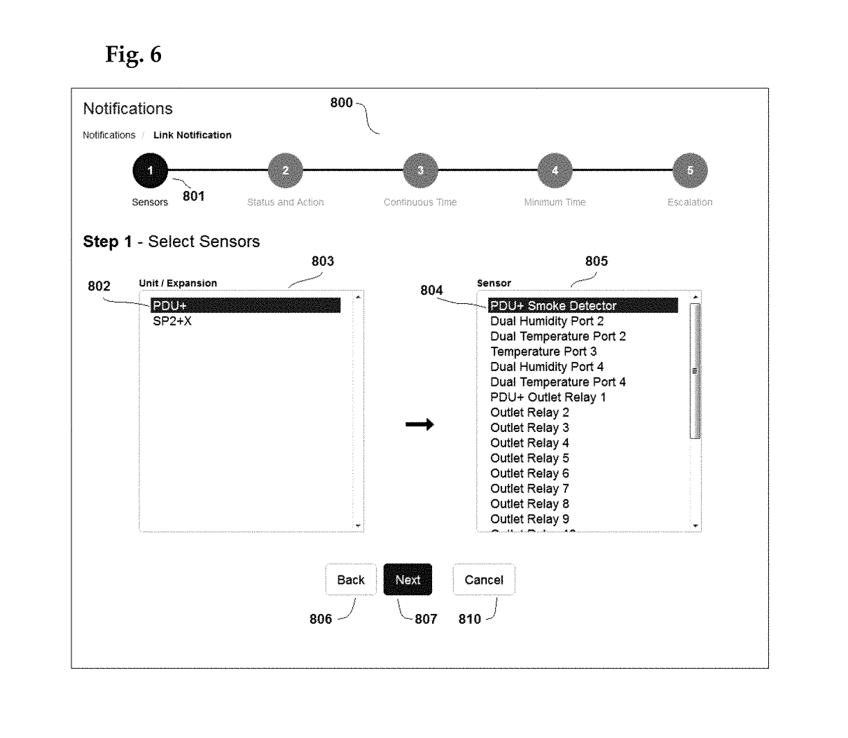

In FIG. 6, the figure depicts a notification policy configuration web page 800 where the user is on the first step 801 of the notification policy configuration. In this page, the user selects the monitored sensor which status change will trigger the execution of an action policy. The user first selects the unit 802 among a list of units 803 where the sensor is connected to, and then the requested sensor 804 (here a Smoke Detector sensor) among a list of sensors 805 that are attached to that unit 802. When the selection is done, the user is able to either go back to previous page 806, go to next step 807 of the notification policy configuration, or cancel the notification policy configuration 810.

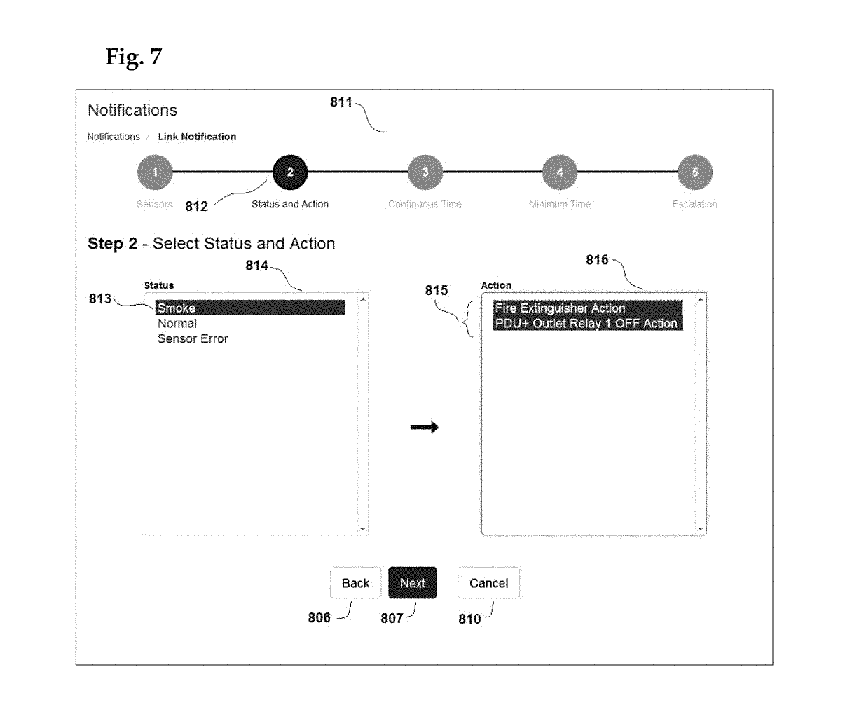

In FIG. 7, the figure depicts a notification policy configuration web page 811 where the user is on the second step 812 of the notification policy configuration. In this page, the user selects the status of the selected sensors and the action policy to execute when sensors change to corresponding status. The user first selects the desired status 813 among a list of available statuses 814, and the desired action policies 815 (PDU Outlet Relay OFF and Fire Extinguishant release) among a list of possible action policies 816. When the selection is done, the user is able to either go back to previous page 806, go to next step 807 of the notification policy configuration, or cancel the notification policy configuration 810.

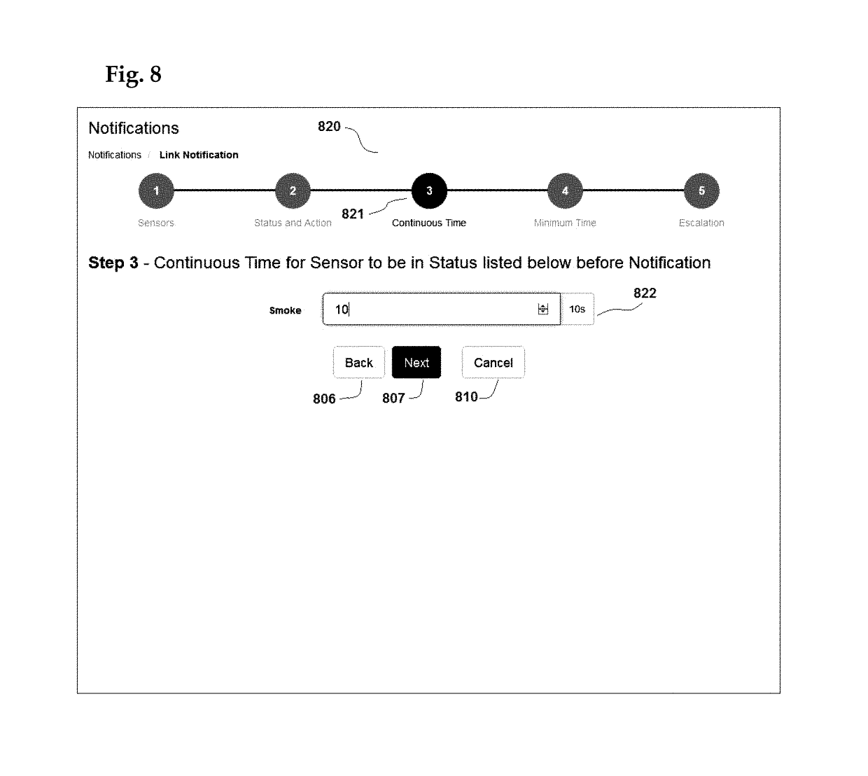

In FIG. 8, the figure depicts a notification policy configuration web page 820 where the user is on the third step 821 of the notification policy configuration. In this page, the user configure a continuous time parameter 822 which corresponds the duration that the desired sensors have to be their triggering status before executing the action policies, this is to avoid false alarms. When the configuration is done, the user is able to either go back to previous page 806, go to next step 807 of the notification policy configuration, or cancel the notification policy configuration 810.

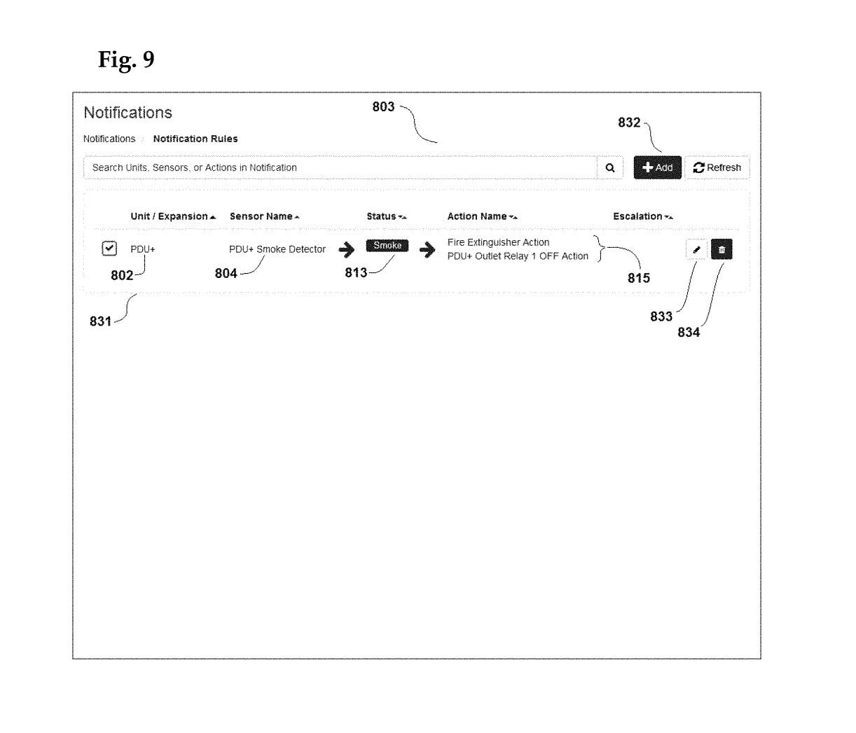

In FIG. 9, the figure depicts a notification policy summary web page 830 where the user has completed all configuration steps of the notification policy configuration. The web page includes a table 831 which displays the unit 802 where the sensor 804 is connected to, the sensor statuses 813 that triggers the indicated notification action policies 815 (PDU Outlet Relay OFF and Fire Extinguishant release). The user is able to create 832 a new notification policy, or to edit 833 or delete 834 an existing notification policy.

Accordingly, it is to be understood that the embodiments of the invention herein described are merely illustrative of the application of the principles of the invention. Reference herein to details of the illustrated embodiments is not intended to limit the scope of the claims, which themselves recite those features regarded as essential to the invention.

What is claimed is:

1. A 0U, rack-mounted power distribution, environment monitoring, and fire-protection apparatus for protecting equipment mounted in the rack, said apparatus comprising:
a) an enclosure mounted in a 0U configuration in unused space in the rack, comprising
i) a power input;
ii) a control module within the enclosure, comprising:
A) a main controller comprising a processor having memory;
B) a communication interface coupled to the processor of the main controller, having a communication port for communicating with a remote user system;
C) at least one sensor interface coupled to the processor of the main controller, having at least one sensor input;
D) at least one power-control relay coupled to the power input, having a power output and a control input, wherein power is provided from the power input to the power output by the power-control relay, and the power-control relay disconnects power from the power output in response to a signal on the control input; and
E) a power-control interface coupled to the processor of the main controller, having at least one power-control output coupled to the control input of at least one power-control relay; and
iii) at least one outlet for powering equipment in the rack connected to the power output of the at least one power-control relay; and
b) at least one smoke detector coupled to at least one sensor input of the at least one sensor interface of the control module;
wherein the processor of the main controller is programmed such that when the processor of the main controller detects a predetermined status on at least one sensor interface the processor of the main controller takes at least one action comprising raising a signal on at least one power-control output to cause the at least one power-control relay coupled to the power-control output to disconnect the power on the power output of the power-control relay.

2. The 0U, rack-mounted, power distribution, environment monitoring, and fire-protection apparatus of claim 1, further comprising at least one fire extinguisher controller coupled to the processor of the main controller, and the processor of the main controller is programmed such that when the processor of the main controller detects a predetermined status on at least one sensor interface, the at least one action taken by the processor of the main controller further comprises raising a signal on an output of the at least one fire extinguisher controller.

3. The 0U, rack-mounted, power distribution, environment monitoring, and fire-protection apparatus of claim 2, further comprising at least one fire extinguishing container having an operating input coupled to the output of at least one fire extinguisher controller, such that the at least one fire extinguishing container coupled to the output of the at least one fire extinguisher controller releases fire extinguishing agent from the at least one fire extinguishing agent containers into the rack when the processor of the main controller raises a signal on the at least one fire extinguisher control output coupled to the operating input of the fire extinguishing container.

4. The 0U, rack-mounted, power distribution, environment monitoring, and fire-protection apparatus of claim 2, in which the at least one fire extinguisher controller and at least one sensor interface to which at least one smoke detector is coupled are combined in a single fire protection controller.

5. The 0U, rack-mounted, power distribution, environment monitoring, and fire-protection apparatus of claim 1, in which the processor of the main controller is programmed such that when the processor of the main controller detects a predetermined status on at least one sensor interface, the at least one action taken by the processor of the main controller further comprises sending a software network remote shutdown command through a network connected to said communication interface, safely shutting down at least one piece of electronic equipment connected to the network.

6. The 0U, rack-mounted, power distribution, environment monitoring, and fire-protection apparatus of claim 1, further comprising at least one annunciator coupled to the processor of the main controller through an annunciator controller, and the processor of the main controller is programmed such that when the processor of the main controller detects a predetermined status on at least one sensor interface, the at least one action taken by the processor of the main controller further comprises causing the annunciator controller to cause an audible or visual alarm to be provided by the at least one annunciator.

7. The 0U, rack-mounted, power distribution, environment monitoring, and fire-protection apparatus of claim 1, in which there are a plurality of power-control relays, the control input of each power-control relay being coupled to one of a plurality of power-control outputs of the power-control interface, and the at least one action taken by the processor of the main controller comprises raising a signal on each of the plurality of power-control outputs of the power-control interface sequentially in a timed manner.

8. The 0U, rack-mounted, power distribution, environment monitoring, and fire-protection apparatus of claim 1, further comprising at least one dry contact output, relay, or valve sensor coupled to the processor of the main controller through an auxiliary equipment controller, and the processor of the main controller is programmed such that when the processor of the main controller detects a predetermined status on at least one sensor interface, the at least one action taken by the processor further comprises sending a signal to cause the auxiliary equipment controller to operate the at least one dry contact output, relay, or valve sensor.

9. The 0U, rack-mounted, power distribution, environment monitoring, and fire-protection apparatus of claim 1, further comprising at least one louver or door coupled to the processor of the main controller through an auxiliary equipment controller, and the processor of the main controller is programmed such that when the processor of the main controller detects a predetermined status on at least one sensor interface, the at least one action taken by the processor of the main controller further comprises sending a signal to cause the auxiliary equipment controller to close the louver or door.

10. The 0U, rack-mounted, power distribution, environment monitoring, and fire-protection apparatus of claim 1, further comprising at least one fan coupled to the processor of the main controller through an auxiliary equipment controller, and the processor of the main controller is programmed such that when the processor detects a predetermined status on at least one sensor interface, the at least one action taken by the processor of the main controller further comprises sending a signal to cause the auxiliary equipment controller to turn off the fan.

11. The 0U, rack-mounted, power distribution, environment monitoring, and fire-protection apparatus of claim 1, further comprising at least one air conditioner or cooling device coupled to the processor of the main controller through an auxiliary equipment controller, and the processor of the main controller is programmed such that when the processor detects a predetermined status on at least one sensor interface, the at least one action taken by the processor of the main controller further comprises sending a signal to cause the auxiliary equipment controller to turn off the air conditioner or cooling device.

12. The 0U, rack-mounted, power distribution, environment monitoring, and fire-protection apparatus of claim 1, in which the apparatus further comprises at least one sensor coupled to the processor of the main controller through at least one sensor interface, wherein the sensor is selected from the group consisting of heat detector, hydrogen sensor, water detector, dry contact input sensor, voltage measurement sensor, current measurement sensor, power measurement sensor, voltage presence sensor, motion detector, humidity sensor, pressure sensor, airflow sensor, dust detection sensor, and light sensor.

13. The 0U, rack-mounted, power distribution, environment monitoring, and fire-protection apparatus of claim 1, in which the processor of the main controller is programmed such that when the processor of the main controller detects a predetermined status on at least one sensor interface, the predetermined status must be maintained for a period of time before the processor of the main controller takes the at least one action.

14. The 0U, rack-mounted, power distribution, environment monitoring, and fire-protection apparatus of claim 1, in which there are a plurality of sensors coupled to the processor of the main controller through the at least one sensor interface, the plurality of sensors including at least one additional smoke detector.

15. The 0U, rack-mounted, power distribution, environment monitoring, and fire-protection apparatus of claim 13, in which the processor of the main controller is programmed such that when the processor detects a predetermined status on at least one sensor interface from a first sensor, the processor waits until the processor of the main controller detects a predetermined status on at least one sensor interface from at least a second sensor before the processor of the main controller takes the at least one action.

16. The 0U, rack-mounted, power distribution, environment monitoring, and fire-protection apparatus of claim 1, in which the enclosure is mounted in unused space at a rear of the rack.

17. The 0U, rack-mounted, power distribution, environment monitoring, and fire-protection apparatus of claim 1, in which the enclosure is mounted vertically in unused space in the rack.

18. A 0U, rack-mounted power distribution, environment monitoring, and fire-protection apparatus for protecting equipment mounted in the rack, said apparatus comprising:
a) an enclosure mounted in a 0U configuration in unused space in the rack, comprising
i) a power input;
ii) a control module within the enclosure, comprising:
A) a main controller comprising a processor having memory;
B) a communication interface coupled to the processor of the main controller, having a communication port for communicating with a remote user system;
C) at least one sensor interface coupled to the processor of the main controller, having at least one sensor input;
D) at least one power-control relay coupled to the power input, having a power output and a control input, wherein power is provided from the power input to the power output by the power-control relay, and the power-control relay disconnects power from the power output in response to a signal on the control input; and
E) a power-control interface coupled to the processor of the main controller, having at least one power-control output coupled to the control input of at least one power-control relay; and
iii) at least one outlet for powering equipment in the rack connected to the power output of the at least one power-control relay;
b) at least one smoke detector coupled to the at least one sensor interface of the control module;
wherein the processor of the main controller is programmed such that when the processor detects a predetermined status on at least one sensor interface, the at least one action taken by the processor of the main controller further comprises raising a signal on at least one fire extinguisher control output; and
wherein the processor of the main controller is programmed such that when the processor of the main controller detects a predetermined status on at least one sensor interface the processor takes at least one action comprising raising a signal on at least one power-control output to cause the at least one power-control relay coupled to the power-control output to disconnect the power on the power output of the power-control relay; and
c) at least one fire extinguishing container having an operating input coupled to the at least one fire extinguisher control output of the control module, such that the at least one fire extinguishing container coupled to the fire extinguisher control output releases fire extinguishing agent from the at least one fire extinguishing agent containers into the rack when the processor of the main controller raises a signal on the at least one fire extinguisher control output coupled to the operating input of the fire extinguishing container.

19. A method of power distribution, environment monitoring, and fire-protection using a 0U, rack-mounted apparatus for protecting equipment mounted in the rack, said apparatus comprising an enclosure comprising a power input, a control module within the enclosure, the control module comprising a main controller having a processor having memory, a communication interface coupled to the processor for communicating with a remote user system, at least one sensor interface coupled to the processor, at least one power-control relay coupled to the power input, having a power output and a control input, wherein power is provided from the power input to the power output by the power-control relay, and the power-control relay disconnects power from the power output in response to a signal on the control input; and at least one power-control output coupled to the control input of at least one power-control relay; and at least one outlet for powering equipment in the rack connected to the power output of the at least one power-control relay; the method comprising the steps of:
a) mounting the enclosure in a 0U configuration in unused space in the rack;
b) mounting at least one smoke detector in the rack, coupled to the at least one sensor interface of the control module; and
c) when the processor of the main controller detects a predetermined status on at least one sensor interface, the processor of the main controller takes at least one action comprising raising a signal on at least one power-control output to cause the at least one power-control relay coupled to the power-control output to disconnect the power on the power output of the power-control relay.

20. The method of power distribution, environment monitoring, and fire-protection of claim 19, in which the control module further comprises at least one fire extinguisher controller having a control output, and the method further comprises:
d) mounting at least one fire extinguishing container in the rack, the fire extinguishing container having an operating input coupled to the control output of the at least one fire extinguisher controller of the control module;
e) when the processor of the main controller detects a predetermined status on at least one sensor interface, the processor of the main controller raises a signal on at least one fire extinguisher control output; and
f) the fire extinguishing container releasing fire extinguishing agent from the at least one fire extinguishing agent containers into the rack in response to the processor of the main controller raising the signal on the at least one at least one fire extinguishing control output.
